(19) United States
(12) Patent Application Publication
(10) Pub. No.: US 2025/0120242 A1
(43) Pub. Date: Apr. 10, 2025

(54) METHOD FOR IMPROVING INTERFACIAL ADHESION OF ORGANIC SOLAR CELL AND ORGANIC SOLAR CELL

(71) Applicant: SUZHOU INSTITUTE OF NANO-TECH AND NANO-BIONICS (SINANO) , CHINESE ACADEMY OF SCIENCES, Suzhou (CN)

(72) Inventors: Qun LUO, Suzhou (CN); Changqi MA, Suzhou (CN); Zihan XU, Suzhou (CN); Yunfei HAN, Suzhou (CN)

(73) Assignee: SUZHOU INSTITUTE OF NANO-TECH AND NANO-BIONICS (SINANO) , CHINESE ACADEMY OF SCIENCES, Suzhou (CN)

(21) Appl. No.: 18/729,933

(22) PCT Filed: Mar. 22, 2023
(86) PCT No.: PCT/CN2023/083137

§ 371 Date: Jul. 18, 2024

(30) Foreign Application Priority Data
Mar. 30, 2022 (CN) 202210328224.X

(51) Int. Cl. H10K 30/50; H10K 30/81; H10K 30/85; H10K 30/86; H10K 71/10; H10K 71/60; H10K 85/10; H10K 102/20

(52) U.S. Cl. CPC H10K 30/50; H10K 30/81; H10K 30/85; H10K 30/86; H10K 71/10; H10K 71/60; H10K 85/1135; H10K 85/141; H10K 2102/20

(57) ABSTRACT

A method for improving interfacial adhesion of an organic solar cell and an organic solar cell are provided. An elastomer interface layer, which is formed by thermoplastic elastomers, is arranged between at least two adjacent functional layers in the organic solar cell, or, the upper and lower interfaces of at least one functional layer have an enrichment layer formed by enrichment of thermoplastic elastomers. The method includes: arranging an elastomer interface layer at least two adjacent functional layers, or, enriching thermoplastic elastomers at the upper and lower interfaces of at least one functional layer to form an enrichment layer. According to the present application, the thermoplastic elastomers enriched at the interfaces, or the thermoplastic elastomers used as interface layers alone serve as glue between functional layers. The method is simple in process, large in doping window, and small in thickness dependence when independent film formation.

### CROSS REFERENCE TO THE RELATED APPLICATIONS

This application is the national phase entry of International Application No. PCT/CN2023/083137, filed on Mar. 22, 2023, which is based upon and claims priority to Chinese Patent Application No. 202210328224.X, filed on Mar. 20, 2022, the entire contents of which are incorporated herein by reference.

### TECHNICAL FIELD

The present application relates to a preparation method of an organic solar cell, particularly to a method for improving the interfacial adhesion of an organic solar cell by enrichment of thermoplastic elastomers, as well as a corresponding organic solar cell and a preparation method thereof, belonging to the technical field of organic solar cell devices.

### BACKGROUND

Organic solar cells have received more and more attentions due to many advantages such as full solution preparation, light weight and wide material sources. Flexible organic solar cells can be applied to irregular surfaces such as human self-powered sensors, various roofs and tent surfaces, and therefore the flexible organic solar cells are required to have good mechanical stability.

Among them, the main structure of an inverted organic solar cell is a substrate/metal electrode/electron transport layer/active layer/molybdenum oxide/metal electrode. Since the organic solar cell is prepared layer by layer and multiple-layer materials are different materials which have different characters and include organic matters, metals, metal oxides and the like. When the organic solar cell is bent, stretched and crimped, the contact between various layers, especially a poor interface compatibility between the active layer and the zinc oxide and molybdenum oxide easily causes interface detachment, even cracks, thereby decaying cell photoelectric conversion efficiency, even leading to cell damage. Consequently, there is a need to consider not only the stability of the above layers themselves but also adhesion between various layers when the mechanical stability of the organic solar cell is improved.

At present, methods for improving the mechanical stability of flexible organic solar cells mainly focus on modification, decoration or replacement of each layer of the organic solar cell. The first method is to modify a flexible transparent conductive electrode in the organic solar cell; the second method is to perform doping or surface modification on an inorganic electron transport layer; the third method is to replace an inorganic hole transport layer with a copolymer polyolefin elastomer (POE) of ethylene and butene. These methods can improve the mechanical stability of the flexible organic solar cell, but the three methods make preparation of the organic solar cell more complex and costly. Although an organic material has better mechanical property than an inorganic film, a photoelectric organic film still has poor mechanical property because it typically contains crystalline and amorphous phases. To this end, the researchers conduct doping on the active layer to improve the mechanical stability of the active layer itself to improve the mechanical stability of the entire cell. However, a doping window is relatively small, so it is difficultly applied to industrialized preparation.

### SUMMARY

The main objective of the present application is to provide a method for improving the interfacial adhesion of an organic solar cell.

Another objective of the present application is also to provide an organic solar cell with excellent anti-bending property and a preparation method thereof.

In order to achieve the previous objectives of the present disclosure, the technical solution adopted by the present application is as follows:

The embodiments of the present application provide an organic solar cell, comprising a conductive substrate, a hole transport layer, an active layer, an electron transport layer, a metal electrode and other functional layers, wherein an elastomer interface layer, which is formed by thermoplastic elastomers, is arranged between at least two adjacent functional layers, or, the upper and lower interfaces of at least one functional layer have an enrichment layer formed by enrichment of thermoplastic elastomers.

Further, the elastomer interface layer is arranged between the active layer and the hole transport layer and/or the electron transport layer, the elastomer interface layer is formed by the thermoplastic elastomers, or, the upper and lower interfaces of the active layer have the enrichment layer formed by enrichment of the thermoplastic elastomers.

Further, the elastomer interface layer is arranged between the electron transport layer and the electrode, or between the hole transport layer and the electrode.

The embodiments of the present application provide a method for improving the interfacial adhesion of an organic solar cell comprising a conductive substrate, a hole transport layer, an active layer, an electron transport layer and a metal electrode, comprising:
arranging an elastomer interface layer, which is formed by thermoplastic elastomers, between at least two adjacent functional layers, or, enriching the thermoplastic elastomers at upper and lower interfaces of at least one functional layer to form an enrichment layer.

The embodiments of the present application also provide a preparation method of an organic solar cell, comprising:
arranging an elastomer interface layer, which is formed by thermoplastic elastomers, between at least two adjacent functional layers, or, enriching the thermoplastic elastomers at upper and lower interfaces of at least one functional layer to form an enrichment layer.

In some embodiments, the preparation method comprises:
providing a conductive substrate;
forming a hole transport layer on the conductive substrate;
forming an active layer on the hole transport layer;
allowing the thermoplastic elastomers to form an elastomer interface layer between the electron transport layer and the active layer according to the previous method;
forming an electron transport layer on the elastomer interface layer; and
forming a metal electrode on the electron transport layer.

In some embodiments, a preparation method of another organic solar cell comprises:
providing a conductive substrate;
forming an electron transport layer on the conductive substrate;
forming an active layer on the electron transport layer;
allowing thermoplastic elastomers to form an elastomer interface layer between the electron transport layer and the active layer according to the previous method;
forming a hole transport layer on the elastomer interface layer; and
forming a metal electrode on the hole transport layer.

The embodiments of the present application also provide a preparation method of another organic solar cell, wherein a method for preparing the active layer comprises: in the process of forming the active layer, allowing the thermoplastic elastomers to be spontaneously enriched at the upper and lower interfaces of the active layer to form an enrichment layer according to the previous method.

The embodiments of the present application also provide a preparation method of another organic solar cell, comprising: allowing the thermoplastic elastomers to be formed between the electron transport layer and the electrode, or between the hole transport layer and the electrode, and arranging an elastomer interface layer between the electron transport layer and the electrode, or between the hole transport layer and the electrode.

Compared with the prior art, the present application has the beneficial effects:

According to the present application, the thermoplastic elastomers are enriched at interfaces, or the thermoplastic elastomers are used as interface layers alone, the thermoplastic elastomers become glue between functional layers, such as between the active layer and upper and lower hole transport layers or the electrode transport layer. This method adopts cheap commercial thermoplastic elastomers, and is simple in process, large in doping window, and small in thickness dependence when independent film formation; when the organic solar cell is prepared by using the active layer involved in the present invention, the prepared organic solar cell has high photoelectric conversion efficiency, strong adhesion between the active layer and the hole transport layer or the electron transport layer, and good cell mechanical stability.

### BRIEF DESCRIPTION OF THE DRAWINGS

In order to more clearly illustrate the technical solutions in the embodiments of the present application or in the prior art, the accompanying drawings required for use in the embodiments or the prior art will be simply presented below, obviously, accompanying drawings described below are only some embodiments of the present application, and other accompanying drawings can also be obtained by persons of ordinary skill in the art according to these accompanying drawings without creative efforts.

FIG. 1 is a structural diagram of a device in which thermoplastic elastomers are enriched at an upper interface of an active layer in an organic solar cell according to a typical embodiment of the present application;

FIG. 2 is a structural diagram of a device in which thermoplastic elastomers are enriched at a lower interface of an active layer in an organic solar cell according to a typical embodiment of the present application;

FIG. 3 is a structural diagram of a device in which upper and lower interfaces of an active layer have an enrichment layer formed by enrichment of thermoplastic elastomers according to a typical embodiment of the present application;

FIG. 4 is a normalized UV-visible absorption spectrogram of active layer PM6:Y6:SEBS in comparative example 1 and examples 1-3 when a weight ratio of SEBS to PM6 is 0%-100% according to the present application;

FIG. 5 is an adhesion bar graph of active layer PM6:Y6:SEBS in comparative example 1 and examples 1-3 when a weight ratio of SEBS to PM6 is 0%-100% according to the present application;

FIG. 6 is a picture showing that addition of SEBS prevents the detachment of MoO₃ and an Al film in example 2 of the present application;

FIG. 7 is a normalized UV-visible absorption spectrogram of an SEBS upper interface layer based on active layer PM6:Y6 in example 13 of the present application;

FIG. 8 is a picture showing that addition of SEBS prevents the detachment of MoO₃ and an Al film in example 14 of the present application; and

FIG. 9 is a picture showing that the detachment of MoO₃ and Al does not occur when SEBS is used as an upper interface adhesion layer of PM6:Y6 active layer in example 14 of the present application.

### DETAILED DESCRIPTION OF THE EMBODIMENTS

In view of the defects of the prior art, the inventors of this case propose the technical solution of the present application through long-term research and lots of practices for the purpose of providing a device structure for enrichment at an organic solar cell interface based on thermoplastic elastomers, and a preparation method of this structure. The enrichment of the thermoplastic elastomers at the interface of the organic solar cell can be achieved by doping the thermoplastic elastomers in an active layer so as to be spontaneously enriched at the upper and lower interfaces of the active layer, or by directly preparing the thermoplastic elastomers between the upper and lower interface layers (i.e., functional layers such as a hole transport layer and an electron transport layer) of the active layer, as an elastomer interface layer.

Next, the technical solution of the present application will be clearly and completely described, obviously, the described embodiments are some embodiments of the present application, but not all the embodiments. Based on the embodiments of the present application, other embodiments obtained by persons of ordinary skill in the art without creative efforts are all included within the scope of protection of the present application.

One aspect of the embodiments of the present application provides a method for improving the interfacial adhesion of an organic solar cell comprising a conductive substrate, a hole transport layer, an active layer, an electron transport layer and a metal electrode. The method comprises: arranging an elastomer interface layer, which is formed by thermoplastic elastomers, between at least two adjacent functional layers, or, enriching the thermoplastic elastomers at upper and lower interfaces of at least one functional layer to form an enrichment layer.

In some embodiments, the thermoplastic elastomer includes a combination of any one or more than two of a styrenic thermoplastic elastomer, an olefin thermoplastic elastomer, a diene thermoplastic elastomer, a vinyl chloride thermoplastic elastomer, a polyurethane thermoplastic elastomer, ester thermoplastic elastomer, an amide thermoplastic elastomer, an organic fluorine thermoplastic elastomer, an organic silicon thermoplastic elastomer and an ethylene thermoplastic elastomer, but is not limited thereto.

In some embodiments, the method for improving the interfacial adhesion of the organic solar cell comprises:
allowing a mixed system containing a donor material, an acceptor material and thermoplastic elastomers to form an active layer, wherein the thermoplastic elastomers are spontaneously enriched at the upper and lower interfaces of the active layer to form an enrichment layer;
or, allowing the thermoplastic elastomers to be formed between the active layer and the hole transport layer and/or the electron transport layer to form the elastomer interface layer; and
arranging the elastomer interface layer between the active layer and the hole transport layer and/or the electronic transport layer, or, the upper and lower interfaces of the active layer having an enrichment layer formed by enrichment of thermoplastic elastomers.

In some embodiments, the method for improving the interfacial adhesion of the organic solar cell comprises: forming the thermoplastic elastomer between the metal electrode and the hole transport layer and/or the electron transport layer to form the elastomer interface layer.

In some embodiments, the method comprises: doping the thermoplastic elastomers into the active layer composed of a donor material and an acceptor material, and enriching the thermoplastic elastomers on the upper and lower surfaces of the active layer to form a thin layer, i.e., an enrichment layer.

In some more specific embodiments, the method comprises:
mixing a donor material with an acceptor material to form active layer ink;
dissolving thermoplastic elastomers into a first solvent, and then blending the above mixture with the active layer ink to form the active layer.

Wherein the above donor material and the acceptor material can use materials commonly used in the industry, but are not limited herein.

In some embodiments, the first solvent comprises a combination of any one or more than two of chloroform, chlorobenzene, tetrahydrofuran, dichlorobenzene, toluene, xylene and trimethylbenzene, preferably chloroform and/or chlorobenzene, but is not limited thereto.

In some embodiments, when the thermoplastic elastomers are blended with the active layer, a mass ratio of the thermoplastic elastomers to the donor material is less than 2:1, in other words, a doping ratio of the thermoplastic elastomers is 0-2 times the mass of the donor material in the active layer, and thermoplastic elastomers of different thicknesses can be spontaneously enriched at the upper and lower interfaces of the active layer.

In some embodiments, the doping ratio of the thermoplastic elastomers is preferably 0.5-1.5 times the mass of the donor material in the active layer.

In some embodiments, the thickness of the active layer is 20-1000 nm, preferably 100-150 nm.

In some embodiments, the thickness of the enrichment layer is 0.5-20 nm, preferably 2-5 nm.

In some more specific embodiments, an achievement method for direct preparation of the thermoplastic elastomers between the upper and lower interface layers (i.e., a hole transport layer and/or an electron transport layer) of the active layer as an elastomer interface layer comprises:
dissolving thermoplastic elastomers into a selected solvent, and then deposing the formed thermoplastic elastomer solution on the surface of the active layer, the electron transport layer or the hole transport layer to form the elastomer interface layer (also referred to as a thermoplastic elastomer layer).

In some embodiments, the thickness of the elastomer interface layer is 0.1-50 nm, preferably 2-10 nm.

In some embodiments, the preparation method of the elastomer interface layer includes any one of spin coating, scratch coating, slit coating, gravure printing and inkjet printing, but is not limited thereto.

Further, when the thermoplastic elastomer solution is deposited above the active layer, the selected solvent is a second solvent which includes a combination of any one or more than two of an alcohol solvent, cycloalkane and alkane, preferably cycloalkane, but is not limited thereto.

Further, when the thermoplastic elastomer solution is deposited under the active layer, the selected solvent is a third solvent which includes a combination of any one or more than two of an alcohol solvent, cycloalkane, alkane, chloroform, chlorobenzene, tetrahydrofuran, dichlorobenzene, toluene, xylene and trimethylbenzene, preferably methanol, but is not limited thereto.

Another aspect of the embodiments of the present application also provides an organic solar cell, comprising a conductive substrate, a hole transport layer, an active layer, an electron transport layer and a metal electrode, wherein an elastomer interface layer, which is formed by thermoplastic elastomers, is arranged between at least two adjacent functional layers, or, the upper and lower interfaces of at least one functional layer have an enrichment layer formed by enrichment of thermoplastic elastomers.

In some embodiments, the types of the thermoplastic elastomers are described as above, and are not described in detail herein.

In some embodiments, the thickness of the active layer is 20-1000 nm, preferably 100-150 nm.

In some embodiments, the thickness of the enrichment layer is 0.5-20 nm, preferably 2-5 nm.

In some embodiments, the thickness of the elastomer interface layer is 0.1-50 nm, preferably 2-10 nm.

In some embodiments, the elastomer interface layer, which the elastomer interface layer is formed by the thermoplastic elastomers, is arranged between the active layer and the hole transport layer and/or the electron transport layer, or, the upper and lower interfaces of the active layer have an enrichment layer formed by the thermoplastic elastomers.

In some more specific embodiments, when the organic solar cell is in an orthostatic structure, the organic solar cell comprises a conductive substrate, a hole transport layer, an elastomer interface layer formed by thermoplastic elastomers, an active layer, the elastomer interface layer formed by the thermoplastic elastomers, an electron transport layer and a metal electrode which are successively laminated (from bottom to top).

In other some more specific embodiments, when the organic solar cell is in an inverted structure, the organic solar cell comprises a conductive substrate, an electron transport layer, an elastomer interface layer formed by thermoplastic elastomers, an active layer, the elastomer interface layer formed by the thermoplastic elastomers, a hole transport layer and a metal electrode which are successively laminated (from bottom to top).

Where the elastomer interface layer formed by the thermoplastic elastomers can only contain one layer, or can simultaneously contain two layers.

In some embodiments, the elastomer interface layer is arranged between the electron transport layer and the electrode, or between the hole transport layer and the electrode.

In some more specific embodiments, when the organic solar cell is in an orthostatic structure, the organic solar cell comprises a conductive substrate, a hole transport layer, an active layer, an electron transport layer, an elastomer interface layer formed by thermoplastic elastomers and a metal electrode which are successively laminated.

In other some more specific embodiments, when the organic solar cell is in an inverted structure, the organic solar cell comprises a conductive substrate, an electron transport layer, an active layer, a hole transport layer, an elastomer interface layer formed by thermoplastic elastomers and a metal electrode which are successively laminated.

In some embodiments, the conductive substrate comprises a polyethylene terephthalate, polyethylene naphthalate or polyimide flexible film covered with any one of a metal nanowire, a metal oxide, a metal grid, graphene and a carbon nanotube on the surface.

Further, the conductive substrate is the polyethylene terephthalate (PET) flexible film covered with the metal nanowire on the surface.

Where the thickness of the conductive substrate is related to a specific electrode material and mostly limited by transmittance and square resistance, the square resistance of a high-performance conductive substrate is generally 10Ω/□ or even lower, at this moment, the higher transmittance is better.

In some embodiments, the material of the electron transport layer includes a combination of any one or more than two of a zinc oxide nanoparticle, sol-gel zinc oxide, PFN-Br and PDINO, but is not limited thereto.

Further, the electron transport layer is the zinc oxide nanoparticle.

Further, the thickness of the electron transport layer is 10-30 nm.

In some embodiments, the material of the hole transport layer comprises molybdenum oxide and/or PEDOT:PSS and the like, preferably molybdenum oxide.

Further, the thickness of the hole transport layer is 10-30 nm.

Further, the active layer is a donor and acceptor blending system having photovoltaic property.

Further, the material of the metal electrode includes aluminum, silver or gold undergoing vacuum evaporation, or a silver nanowire prepared by using spin coating, scraping coating, slit coating, inkjet printing or other methods, but not limited thereto.

Further, the thickness of the metal electrode is 50-1000 nm.

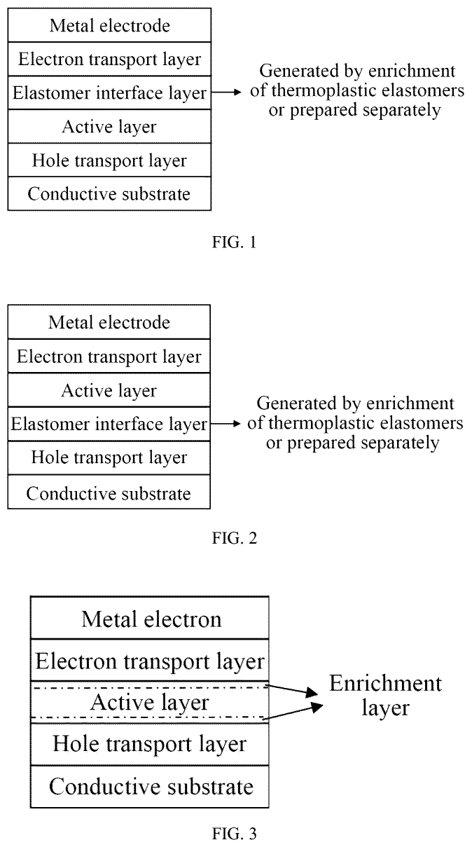

In some more specific embodiments, as shown in FIG. 1, when the thermoplastic elastomers are enriched at the upper interface of the active layer of the organic solar cell, the structure of the organic solar cell from bottom to top successively comprises: a conductive substrate, a hole transport layer, an active layer, an elastomer interface layer formed by the thermoplastic elastomers, an electron transport layer and a metal electrode.

In some more specific embodiments, as shown in FIG. 2, when the thermoplastic elastomers are enriched at the lower interface of the active layer of the organic solar cell, the structure of the organic solar cell from bottom to top successively comprises: a conductive substrate, a hole transport layer, an elastomer interface layer formed by the thermoplastic elastomers, an active layer, an electron transport layer and a metal electrode.

In some more specific embodiments, as shown in FIG. 3, the structure of the organic solar cell from bottom to top successively comprises: a conductive substrate, a hole transport layer, an active layer, an electron transport layer and a metal electrode, wherein, the upper and lower interfaces of the active layer have an enrichment layer formed by the thermoplastic elastomers.

In the present application, a mechanism that the arrangement of the elastomer interface layer can improve the adhesion lies in that: a hydrogen bond is formed between H atoms contained in the elastomer interface layer formed by the thermoplastic elastomers and F, N and O atoms that may be contained in the active layer/F, N and O atoms that may be contained in the electron transport layer, increasing an action force (i.e., adhesion) between the elastomer interface layer and the active layer/electron transport layer or other functional layers.

Further, the mechanism that the arrangement of the elastomer interface layer can improve the adhesion is basically the same as that of the elastomer interface layer, however, the enrichment phenomenon spontaneously occurs here, an uniform enrichment layer (i.e., some areas have enrichment, some areas have no enrichment, some areas have thicker enrichment layers, and some areas have thinner enrichment layers) is not necessarily formed at the interface, and therefore the improvement effect on the adhesion is slightly lower than that on the elastomer interface layer.

Another aspect of the embodiments of the present application also provides a preparation method of an organic solar cell, comprising: arranging an elastomer interface layer, which is formed by thermoplastic elastomers, between at least two adjacent functional layers, or, enriching the thermoplastic elastomers at upper and lower interfaces of at least one functional layer to form an enrichment layer.

Another aspect of the embodiments of the present application also provides a preparation method of an organic solar cell with an orthostatic structure, comprising:
providing a conductive substrate;
forming a hole transport layer on the conductive substrate;
forming an active layer on the hole transport layer;
allowing thermoplastic elastomers to form an elastomer interface layer between the hole transport layer and the active layer according to the previous method;
forming an electron transport layer on the elastomer interface layer; and
forming a metal electrode on the electron transport layer.

The embodiments of the present application also provide a preparation method of an organic solar cell with an inverted structure, comprising:
providing a conductive substrate;
forming an electron transport layer on the conductive substrate;
forming an active layer on the electron transport layer;
allowing thermoplastic elastomers to form an elastomer interface layer between the electron transport layer and the active layer according to the previous method;
forming a hole transport layer on the elastomer interface layer; and
forming a metal electrode on the hole transport layer.

Where the elastomer interface layer formed by the thermoplastic elastomers can only contain one layer, or can simultaneously contain two layers.

The embodiments of the present application also provide a preparation method of another organic solar cell, wherein a method for preparing the active layer comprises: according to the previous method, allowing the thermoplastic elastomers to be spontaneously enriched at the upper and lower interfaces of the active layer in the process of forming the active layer to form an enrichment layer.

The embodiments of the present application also provide a preparation method of another organic solar cell, comprising: allowing thermoplastic elastomers to be formed between the electron transport layer and the electrode, or between the hole transport layer and the electrode, and arranging an elastomer interface layer between the electron transport layer and the electrode, or between the hole transport layer and the electrode.

Specifically, as a preferred embodiment, the preparation method comprises:
providing a conductive substrate;
forming a hole transport layer on the conductive substrate;
forming an active layer on the hole transport layer;
forming an electron transport layer on the active layer;
allowing thermoplastic elastomers to form an elastomer interface layer on the electron transport layer; and
forming a metal electrode on the elastomer interface layer.

Specifically, as a preferred embodiment, the preparation method comprises:
providing a conductive substrate;
forming an electron transport layer on the conductive substrate;
forming an active layer on the electron transport layer;
forming a hole transport layer on the active layer;
allowing thermoplastic elastomers to form an elastomer interface layer on the hole transport layer; and
forming a metal electrode on the elastomer interface layer.

Further, the preparation method of the hole transport layer comprises: preparing the hole transport layer by using any one of vacuum evaporation, spin coating, scratch coating, slit coating, gravure printing, inkjet printing and other methods.

Further, the preparation method of the metal electrode comprises: preparing the metal electrode by using any one of vacuum evaporation, spin coating, scratch coating, slit coating, inkjet printing and other methods.

Further, the metal electrode is aluminum, silver and gold undergoing vacuum evaporation, or a silver nanowire prepared by using spin coating, scratch coating, slit coating, inkjet printing and other methods, with a thickness of 50-1000 nm.

Furthermore, the metal electrode is vacuum evaporated aluminum with a thickness of 150 nm.

Next, the specific embodiments of the present application will be described in detail in combination with examples. The following examples are used for illustrating the present application, but are not intended to limit the scope of the present application. On the contrary, providing these examples are intended to explain the principle and actual application of the present invention, so as to make other technicians in the art more understand various embodiments of the present application and various modifications suitable for specific predicted applications.

Unless specified otherwise, various raw materials, production equipment, test equipment and the like used in the following examples are all available in the markets. Test methods adopted are also test methods well-known in the art.

### Comparative Example 1

An inverted organic solar cell structure in this example from bottom to top comprised a conductive substrate, an electron transport layer, an active layer, a hole transport layer and a metal electrode, respectively. The conductive substrate was a polyethylene terephthalate film covered with silver nanowires on the surface; the electron transport layer was a zinc oxide nanoparticle film with a thickness of 10 nm; in the active layer, a donor material was PM6, an acceptor material was Y6, a mass ratio of the donor material to the acceptor material was 1:1.2, and the concentration of a solution was 8 mg/ml based on PM6; the hole transport layer was vacuum evaporated molybdenum oxide with a thickness of 10 nm; the metal electrode is vacuum evaporated aluminum with a thickness of 150 nm. The performances of the organic solar cell were tested under standard test conditions (AM1.5, 100 mW/cm²). The open circuit voltage (V_{oc}) of the cell is measured as 0.82 V, the short circuit current density was measured as 24.97 mA/cm², the filling factor (FF) was measured as 69.51%, and the power conversion efficiency (PCE) was measured as 14.21%. By testing, the surface adhesion of the active layer in this comparative example was 9.38 nN. By testing, the power conversion efficiency (PCE) of the cell after 5000 times of outward bending cycles was maintained as 83% of an initial value.

### Example 1

An inverted organic solar cell structure in this example from bottom to top comprised a conductive substrate, an electron transport layer, a styrene ethylene butylene styrene (SEBS) doped active layer, a hole transport layer and a metal electrode, respectively. The conductive substrate was a polyethylene terephthalate film covered with silver nanowires on the surface; the electron transport layer was a zinc oxide nanoparticle film with a thickness of 10 nm; in the active layer, a donor material was PM6, an acceptor material was Y6, a mass ratio of the donor material to the acceptor material was 1:1.2, and the concentration of a solution was 8 mg/ml based on PM6; the selected thermoplastic elastomer was SEBS, and its ratio was 10%; the hole transport layer was evaporated molybdenum oxide with a thickness of 10 nm; the metal electrode was vacuum evaporated aluminum with a thickness of 150 nm. In this ratio, the thermoplastic elastomer enrichment layer formed on the surface of the active layer was 0.5 nm in thickness; the performances of the organic solar cell were tested under standard test conditions (AM1.5, 100 mW/cm²), the open circuit voltage (V_{oc}) of the cell was measured as 0.83 V, the short circuit current density (J_{sc}) was measured as 24.66 mA/cm², the filling factor (FF) was measured as 69.24%, and the power conversion efficiency (PCE) was measured as 14.12%. The surface adhesion of the active layer in this example was 15.39 nN. The power conversion efficiency (PCE) of the cell after 5000 times of outward bending cycles was maintained as 84% of an initial value.

Relative to comparative example 1, the surface adhesion is improved by 164%, and the efficiency maintenance after bending cycle is improved by 1%.

### Example 2

An inverted organic solar cell structure in this example from bottom to top comprised a conductive substrate, an electron transport layer, an SEBS doped active layer, a hole transport layer and a metal electrode, respectively. The conductive substrate was a polyethylene terephthalate film covered with silver nanowires on the surface; the electron transport layer was a zinc oxide nanoparticle film with a thickness of 10 nm; in the active layer, a donor material was PM6, an acceptor material was Y6, a mass ratio of the donor material to the acceptor material was 1:1.2, and the concentration of a solution was 8 mg/ml based on PM6; the selected thermoplastic elastomer was SEBS, and its ratio was 50%; the hole transport layer was vacuum evaporated molybdenum oxide with a thickness of 20 nm; the metal electrode was vacuum evaporated aluminum with a thickness of 150 nm. In this ratio, the thermoplastic elastomer enrichment layer formed on the surface of the active layer was 3 nm in thickness; the performances of the organic solar cell were tested under standard test conditions (AM1.5, 100 mW/cm²), the open circuit voltage (V_{oc}) of the cell was measured as 0.81 V, the short circuit current density (J_{sc}) was measured as 24.19 mA/cm², the filling factor (FF) was measured as 69.40%, and the power conversion efficiency (PCE) was measured as 13.60%. The surface adhesion of the active layer in this example was 21.75 nN. The power conversion efficiency (PCE) of the cell after 5000 times of outward bending cycles was maintained as 85% of an initial value.

Relative to comparative example 1, the surface adhesion is improved by 232%, and the efficiency maintenance after bending cycle is improved by is improved by 2%.

### Example 3

An inverted organic solar cell structure in this example from bottom to top comprised a conductive substrate, an electron transport layer, an SEBS doped active layer, a hole transport layer and a metal electrode, respectively. The conductive substrate was a polyethylene terephthalate film covered with silver nanowires on the surface; the electron transport layer was a zinc oxide nanoparticle film with a thickness of 10 nm; in the active layer, a donor material was PM6, an acceptor material was Y6, a mass ratio of the donor material to the acceptor material was 1:1.2, and the concentration of a solution was 8 mg/ml based on PM6; the selected thermoplastic elastomer was SEBS, and its ratio was 100%; the hole transport layer was vacuum evaporated molybdenum oxide with a thickness of 10 nm; the metal electrode was vacuum evaporated aluminum with a thickness of 150 nm. In this ratio, the thermoplastic elastomer enrichment layer formed on the surface of the active layer was 10 nm in thickness; the performances of the organic solar cell were tested under standard test conditions (AM1.5, 100 mW/cm²), the open circuit voltage (V_{oc}) of the cell was measured as 0.81 V, the short circuit current density (J_{sc}) was measured as 22.60 mA/cm², the filling factor (FF) was measured as 67.23%, and the power conversion efficiency (PCE) was measured as 12.34%. The surface adhesion of the active layer in this example was 25.55 nN. The power conversion efficiency (PCE) of the cell after 5000 times of outward bending cycles was maintained as 87% of an initial value.

Relative to comparative example 1, the surface adhesion is improved by 274%, and the efficiency maintenance after bending cycle is improved by is improved by 4%.

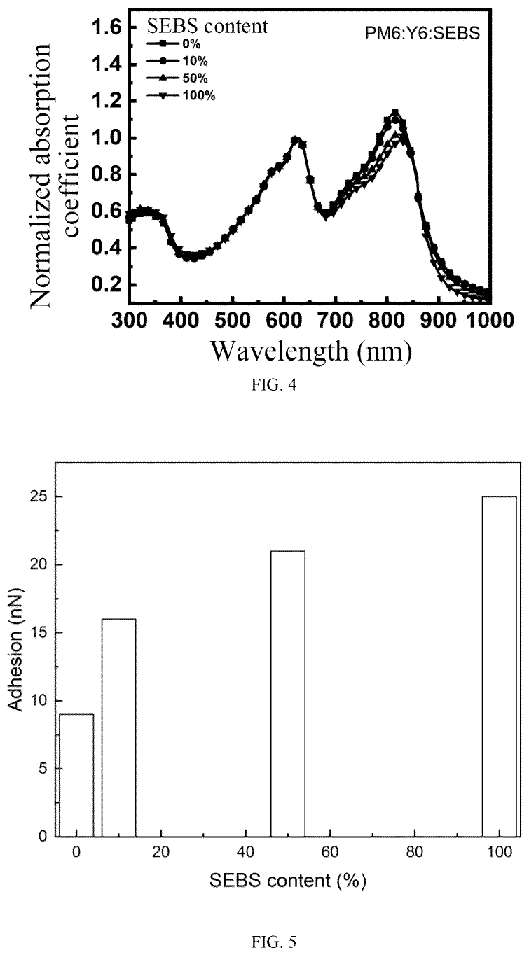

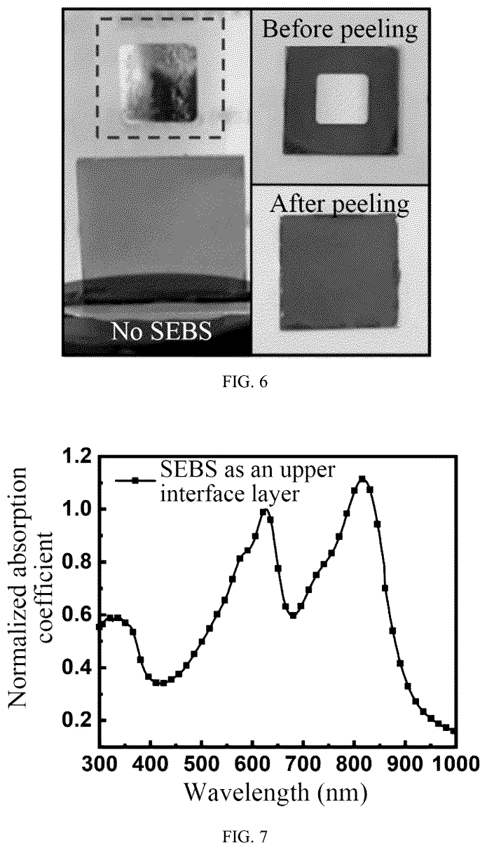

FIG. 4 is a normalized UV-visible absorption spectrogram of active layer PM6:Y6:SEBS in comparative example 1 and examples 1-3 when a weight ratio of SEBS to PM6 is 0%-100%; FIG. 5 is an adhesion bar graph of active layer PM6:Y6:SEBS in comparative example 1 and examples 1-3 when a weight ratio of SEBS to PM6 is 0%-100%. FIG. 6 shows that when SEBS is an adhesive layer, the adhesion of molybdenum oxide and Al on the active layer is improved, and the use of a 3M adhesive tape does not allow the film to fall off. By comparison, complete peeling occurs for a film without SEBS as the adhesive layer.

### Example 4

An inverted organic solar cell structure in this example from bottom to top comprised a conductive substrate, an electron transport layer, an SEBS doped active layer, a hole transport layer and a metal electrode, respectively. The conductive substrate was a polyethylene terephthalate film covered with silver nanowires on the surface; the electron transport layer was a zinc oxide nanoparticle film with a thickness of 10 nm; in the active layer, a donor material was PM6, an acceptor material is Y6, a mass ratio of the donor material to the acceptor material was 1:1.2, and the concentration of a solution was 8 mg/ml based on PM6; the selected thermoplastic elastomer was SEBS, and its ratio was 200%; the hole transport layer was vacuum evaporated molybdenum oxide with a thickness of 20 nm; the metal electrode was vacuum evaporated aluminum with a thickness of 150 nm. In this ratio, the thermoplastic elastomer enrichment layer formed on the surface of the active layer was 20 nm in thickness; the performances of the organic solar cell were tested under standard test conditions (AM1.5, 100 mW/cm²), the open circuit voltage (V_{oc}) of the cell was measured as 0.81 V, the short circuit current density (J_{sc}) was measured as 22.11 mA/cm², the filling factor (FF) was measured as 66.11%, and the power conversion efficiency (PCE) was measured as 11.84%. The surface adhesion of the active layer in this example was 26.79 nN. The power conversion efficiency (PCE) of the cell after 5000 times of outward bending cycles was maintained as 88% of an initial value.

Relative to comparative example 1, the surface adhesion is improved by 286%, and the efficiency maintenance after bending cycle is improved by 5%.

### Example 5

An inverted organic solar cell structure in this example from bottom to top comprised a conductive substrate, an electron transport layer, a thermoplastic polyurethane (TPU) doped active layer, a hole transport layer and a metal electrode, respectively. The conductive substrate was a polyethylene terephthalate film covered with silver nanowires on the surface; the electron transport layer was a zinc oxide nanoparticle film with a thickness of 10 nm; in the active layer, a donor material was PM6, an acceptor material was Y6, a mass ratio of the donor material to the acceptor material was 1:1.2, and the concentration of a solution was 8 mg/ml based on PM6; the selected thermoplastic elastomer was TPU, and its ratio was 50%; the hole transport layer was vacuum evaporated molybdenum oxide with a thickness of 20 nm; the metal electrode was vacuum evaporated aluminum with a thickness of 150 nm. In this ratio, the thermoplastic elastomer enrichment layer formed on the surface of the active layer was 10 nm in thickness; the performances of the organic solar cell were tested under standard test conditions (AM1.5, 100 mW/cm²), the open circuit voltage (V_{oc}) of the cell was measured as 0.81 V, the short circuit current density (J_{sc}) was measured as 24.28 mA/cm², the filling factor (FF) was measured as 69.94%, and the power conversion efficiency (PCE) was measured as 13.82%. The surface adhesion of the active layer in this example was 17.82 nN. The power conversion efficiency (PCE) of the cell after 5000 times of outward bending cycles was maintained as 86% of an initial value.

Relative to comparative example 1, the surface adhesion is improved by 190%, and the efficiency maintenance after bending cycle is improved by 3%.

### Example 6

An inverted organic solar cell structure in this example from bottom to top comprised a conductive substrate, an electron transport layer, a thermoplastic polyimide (TPI) doped active layer, a hole transport layer and a metal electrode, respectively. The conductive substrate was a polyethylene terephthalate film covered with silver nanowires on the surface; the electron transport layer was a zinc oxide nanoparticle film with a thickness of 10 nm; in the active layer, a donor material was PM6, an acceptor material is Y6, a mass ratio of the donor material to the acceptor material was 1:1.2, and the concentration of a solution was 8 mg/ml based on PM6; the selected thermoplastic elastomer was TPI, and its ratio was 50%; the hole transport layer was vacuum evaporated molybdenum oxide with a thickness of 20 nm; the metal electrode was vacuum evaporated aluminum with a thickness of 150 nm. In this ratio, the thermoplastic elastomer enrichment layer formed on the surface of the active layer was 7 nm in thickness; the performances of the organic solar cell were tested under standard test conditions (AM1.5, 100 mW/cm²), the open circuit voltage (V_{oc}) of the cell was measured as 0.81 V, the short circuit current density (J_{sc}) was measured as 24.99 mA/cm², the filling factor (FF) was measured as 69.40%, and the power conversion efficiency (PCE) was measured as 14.30%. The surface adhesion of the active layer in this example was 19.31 nN. The power conversion efficiency (PCE) of the cell after 5000 times of outward bending cycles was maintained as 84% of an initial value.

Relative to comparative example 1, the surface adhesion is improved by 206%, and the efficiency maintenance after bending cycle is improved by 1%.

### Example 7

An inverted organic solar cell structure in this example from bottom to top comprised a conductive substrate, an electron transport layer, a thermoplastic vulcanized rubber (TPV) doped active layer, a hole transport layer and a metal electrode, respectively. The conductive substrate was a polyethylene terephthalate film covered with silver nanowires on the surface; the electron transport layer was a zinc oxide nanoparticle film with a thickness of 10 nm; in the active layer, a donor material was PM6, an acceptor material was Y6, a mass ratio of the donor material to the acceptor material was 1:1.2, and the concentration of a solution was 8 mg/ml based on PM6; the selected thermoplastic elastomer was TPV, and its ratio was 50%; the hole transport layer was vacuum evaporated molybdenum oxide with a thickness of 20 nm; the metal electrode was vacuum evaporated aluminum with a thickness of 150 nm. In this ratio, the thermoplastic elastomer enrichment layer formed on the surface of the active layer was 5 nm in thickness; the performances of the organic solar cell were tested under standard test conditions (AM1.5, 100 mW/cm²), the open circuit voltage (V_{oc}) of the cell was measured as 0.83 V, the short circuit current density (J_{sc}) was measured as 24.79 mA/cm², the filling factor (FF) was measured as 68.99%, and the power conversion efficiency (PCE) was measured as 14.20%. The surface adhesion of the active layer in this example was 20.09 nN. The power conversion efficiency (PCE) of the cell after 5000 times of outward bending cycles was maintained as 86% of an initial value.

Relative to comparative example 1, the surface adhesion is improved by 214%, and the efficiency maintenance after bending cycle is improved by 3%.

### Example 8

An inverted organic solar cell structure in this example from bottom to top comprised a conductive substrate, an electron transport layer, a thermoplastic polyvinyl chloride (TPVC) doped active layer, a hole transport layer and a metal electrode, respectively. The conductive substrate was a polyethylene terephthalate film covered with silver nanowires on the surface; the electron transport layer was a zinc oxide nanoparticle film with a thickness of 10 nm; in the active layer, a donor material was PM6, an acceptor material is Y6, a mass ratio of the donor material to the acceptor material was 1:1.2, and the concentration of a solution was 8 mg/ml based on PM6; the selected thermoplastic elastomer was TPVC, and its ratio was 50%; the hole transport layer was vacuum evaporated molybdenum oxide with a thickness of 20 nm; the metal electrode was vacuum evaporated aluminum with a thickness of 150 nm. In this ratio, the thermoplastic elastomer enrichment layer formed on the surface of the active layer was 2 nm in thickness; the performances of the organic solar cell were tested under standard test conditions (AM1.5, 100 mW/cm²), the open circuit voltage (V_{oc}) of the cell was measured as 0.82 V, the short circuit current density (J_{sc}) was measured as 24.19 mA/cm², the filling factor (FF) was measured as 69.23%, and the power conversion efficiency (PCE) was measured as 13.73%. The surface adhesion of the active layer in this example was 16.82 nN. The power conversion efficiency (PCE) of the cell after 5000 times of outward bending cycles was maintained as 88% of an initial value.

Relative to comparative example 1, the surface adhesion is improved by 179%, and the efficiency maintenance after bending cycle is improved by 5%.

### Example 9

An inverted organic solar cell structure in this example from bottom to top comprised a conductive substrate, an electron transport layer, a thermoplastic polyether ester elastomer (TPEE) doped active layer, a hole transport layer and a metal electrode, respectively. The conductive substrate was a polyethylene terephthalate film covered with silver nanowires on the surface; the electron transport layer was a zinc oxide nanoparticle film with a thickness of 10 nm; in the active layer, a donor material was PM6, an acceptor material was Y6, a mass ratio of the donor material to the acceptor material was 1:1.2, and the concentration of a solution was 8 mg/ml based on PM6; the selected thermoplastic elastomer was TPEE, and its ratio was 50%; the hole transport layer was vacuum evaporated molybdenum oxide with a thickness of 20 nm; the metal electrode was vacuum evaporated aluminum with a thickness of 150 nm. In this ratio, the thermoplastic elastomer enrichment layer formed on the surface of the active layer was 3 nm in thickness; the performances of the organic solar cell were tested under standard test conditions (AM1.5, 100 mW/cm²), the open circuit voltage (V_{oc}) of the cell was measured as 0.82 V, the short circuit current density (J_{sc}) was measured as 23.92 mA/cm², the filling factor (FF) was measured as 68.79%, and the power conversion efficiency (PCE) was measured as 13.49%. The surface adhesion of the active layer in this example was 21.26 nN. The power conversion efficiency (PCE) of the cell after 5000 times of outward bending cycles was maintained as 89% of an initial value.

Relative to comparative example 1, the surface adhesion is improved by 227%, and the efficiency maintenance after bending cycle is improved by 6%.

### Example 10

An inverted organic solar cell structure in this example from bottom to top comprised a conductive substrate, an electron transport layer, a thermoplastic polyamide elastomer (TPAE) doped active layer, a hole transport layer and a metal electrode, respectively. The conductive substrate was a polyethylene terephthalate film covered with silver nanowires on the surface; the electron transport layer was a zinc oxide nanoparticle film with a thickness of 10 nm; in the active layer, a donor material was PM6, an acceptor material is Y6, a mass ratio of the donor material to the acceptor material was 1:1.2, and the concentration of a solution is 8 mg/ml based on PM6; the selected thermoplastic elastomer was TPAE, and its ratio was 30%; the hole transport layer was vacuum evaporated molybdenum oxide with a thickness of 20 nm; the metal electrode was vacuum evaporated aluminum with a thickness of 150 nm. In this ratio, the thermoplastic elastomer enrichment layer formed on the surface of the active layer was 2 nm in thickness; the performances of the organic solar cell were tested under standard test conditions (AM1.5, 100 mW/cm²), the open circuit voltage (V_{oc}) of the cell was measured as 0.82 V, the short circuit current density (J_{sc}) was measured as 24.68 mA/cm², the filling factor (FF) was measured as 69.91%, and the power conversion efficiency (PCE) was measured as 14.15%. The surface adhesion of the active layer in this example was 17.24 nN. The power conversion efficiency (PCE) of the cell after 5000 times of outward bending cycles was maintained as 85% of an initial value.

Relative to comparative example 1, the surface adhesion is improved by 184%, and the efficiency maintenance after bending cycle is improved by 2%.

### Example 11

An inverted organic solar cell structure in this example from bottom to top comprised a conductive substrate, an electron transport layer, a triphenyl phosphate (TPF) doped active layer, a hole transport layer and a metal electrode, respectively. The conductive substrate was a polyethylene terephthalate film covered with silver nanowires on the surface; the electron transport layer was a zinc oxide nanoparticle film with a thickness of 10 nm; in the active layer, a donor material was PM6, an acceptor material was Y6, a mass ratio of the donor material to the acceptor material was 1:1.2, and the concentration of a solution is 8 mg/ml based on PM6; the selected thermoplastic elastomer was TPF, and its ratio is 50%; the hole transport layer was vacuum evaporated molybdenum oxide with a thickness of 20 nm; the metal electrode was vacuum evaporated aluminum with a thickness of 150 nm. In this ratio, the thermoplastic elastomer enrichment layer formed on the surface of the active layer was 6 nm in thickness; the performances of the organic solar cell were tested under standard test conditions (AM1.5, 100 mW/cm²), the open circuit voltage (V_{oc}) of the cell was measured as 0.82 V, the short circuit current density (J_{sc}) was measured as 23.53 mA/cm², the filling factor (FF) was measured as 68.72%, and the power conversion efficiency (PCE) was measured as 13.26%. The surface adhesion of the active layer in this example was 16.86 nN. The power conversion efficiency (PCE) of the cell after 5000 times of outward bending cycles was maintained as 89% of an initial value.

Relative to comparative example 1, the surface adhesion is improved by 180%, and the efficiency maintenance after bending cycle is improved by 6%.

### Example 12

An inverted organic solar cell structure in this example from bottom to top comprised a conductive substrate, an electron transport layer, a thermoplastic silicon vulcanizate (TPSIV) doped active layer, a hole transport layer and a metal electrode, respectively. The conductive substrate was a polyethylene terephthalate film covered with silver nanowires on the surface; the electron transport layer was a zinc oxide nanoparticle film with a thickness of 10 nm; in the active layer, a donor material was PM6, an acceptor material was Y6, a mass ratio of the donor material to the acceptor material as 1:1.2, and the concentration of a solution was 8 mg/ml based on PM6; the selected thermoplastic elastomer was TPSiV, and its ratio was 20%; the hole transport layer was vacuum evaporated molybdenum oxide with a thickness of 20 nm; the metal electrode was vacuum evaporated aluminum with a thickness of 150 nm. In this ratio, the thermoplastic elastomer enrichment layer formed on the surface of the active layer was 1 nm in thickness; the performances of the organic solar cell were tested under standard test conditions (AM1.5, 100 mW/cm²), the open circuit voltage (V_{oc}) of the cell was measured as 0.81 V, the short circuit current density (J_{sc}) was measured as 24.35 mA/cm², the filling factor (FF) was measured as 69.36%, and the power conversion efficiency (PCE) was measured as 13.68%. The surface adhesion of the active layer in this example was 19.12 nN. The power conversion efficiency (PCE) of the cell after 5000 times of outward bending cycles was maintained as 86% of an initial value.

Relative to comparative example 1, the surface adhesion is improved by 204%, and the efficiency maintenance after bending cycle is improved by 3%.

### Example 13

An inverted organic solar cell structure based on a thermoplastic elastomer as an elastomer interface layer in this example from bottom to top comprised a conductive substrate, an electron transport layer, an active layer, an elastomer interface layer (i.e., thermoplastic elastomer layer), a hole transport layer and a metal electrode, respectively. The conductive substrate was a polyethylene terephthalate film covered with silver nanowires on the surface; the electron transport layer was a zinc oxide nanoparticle film with a thickness of 10 nm; a solvent used when the thermoplastic elastomer layer was prepared is cyclohexane, the selected thermoplastic elastomer was SEBS, and the thickness of the elastomer interface layer was 0.1 nm; in the active layer, a donor material was PM6, an acceptor material was Y6, a mass ratio of the donor material to the acceptor material was 1:1.2, and the concentration of a solution was 8 mg/ml based on PM6; the hole transport layer was vacuum evaporated molybdenum oxide with a thickness of 10 nm; the metal electrode was vacuum evaporated aluminum with a thickness of 150 nm. The performances of the organic solar cell were tested under standard test conditions (AM1.5, 100 mW/cm²). The open circuit voltage of the cell was measured as 0.83 V, the short circuit current density was measured as 25.05 mA/cm², the filling factor (FF) was measured as 68.97%, and the power conversion efficiency (PCE) was measured as 14.21%. The surface adhesion of the active layer in this example was 12.48 nN. The power conversion efficiency (PCE) of the cell after 5000 times of outward bending cycles was maintained as 85% of an initial value.

Relative to comparative example 1, the surface adhesion is improved by 117%, and the efficiency maintenance after bending cycle is improved by 2%.

FIG. 7 is a normalized UV-visible absorption spectrogram of an SEBS upper interface layer based on active layer PM6:Y6 in this example.

### Example 14

An inverted organic solar cell structure based on a thermoplastic elastomer as an elastomer interface layer in this example from bottom to top comprised a conductive substrate, an electron transport layer, an active layer, an elastomer interface layer (i.e., thermoplastic elastomer layer), a hole transport layer and a metal electrode, respectively. The conductive substrate was a polyethylene terephthalate film covered with silver nanowires on the surface; the electron transport layer was a zinc oxide nanoparticle film with a thickness of 10 nm; a solvent used when the thermoplastic elastomer layer was prepared was n-hexane, the selected thermoplastic elastomer was SEBS, and the thickness of the elastomer interface layer was 2 nm; in the active layer, a donor material is PM6, an acceptor material was Y6, a mass ratio of the donor material to the acceptor material was 1:1.2, and the concentration of a solution was 8 mg/ml based on PM6; the hole transport layer was vacuum evaporated molybdenum oxide with a thickness of 10 nm; the metal electrode was vacuum evaporated aluminum with a thickness of 150 nm. The performances of the organic solar cell were tested under standard test conditions (AM1.5, 100 mW/cm²). The open circuit voltage of the cell was measured as 0.82 V, the short circuit current density was measured as 24.82 mA/cm², the filling factor (FF) was measured as 69.39%, and the power conversion efficiency (PCE) was measured as 14.13%. The surface adhesion of the active layer in this example was 38.57 nN. The power conversion efficiency (PCE) of the cell after 5000 times of outward bending cycles was maintained as 95% of an initial value.

Relative to comparative example 1, the surface adhesion is improved by 410%, and the efficiency maintenance after bending cycle is improved by 12%.

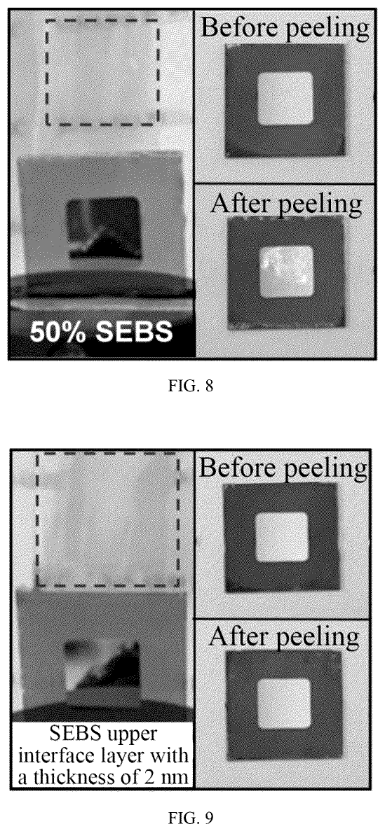

FIG. 8 shows that in this example, the adhesion of MoO₃ and Al on an active layer is improved when SEBS is an upper surface adhesive layer, use of 3M adhesive tap does not allow the film to fall off. By comparison, complete peeling occurs for a film without SEBS as the adhesive layer. FIG. 9 is a picture showing that detachment of MoO₃ and Al does not occur on SEBS as an upper interface adhesion layer of PM6:Y6 active layer.

### Example 15

An inverted organic solar cell structure based on a thermoplastic elastomer as an elastomer interface layer in this example from bottom to top comprised a conductive substrate, an electron transport layer, an active layer, an elastomer interface layer (i.e., thermoplastic elastomer layer), a hole transport layer and a metal electrode, respectively. The conductive substrate was a polyethylene terephthalate film covered with silver nanowires on the surface; the electron transport layer was a zinc oxide nanoparticle film with a thickness of 10 nm; a solvent used when the thermoplastic elastomer layer was prepared is cyclohexane, the selected thermoplastic elastomer was SEBS, and the thickness of the elastomer interface layer was 20 nm; in the active layer, a donor material was PM6, an acceptor material was Y6, a mass ratio of the donor material to the acceptor material was 1:1.2, and the concentration of a solution was 8 mg/ml based on PM6; the hole transport layer was vacuum evaporated molybdenum oxide with a thickness of 10 nm; the metal electrode was vacuum evaporated aluminum with a thickness of 150 nm. The performances of the organic solar cell were tested under standard test conditions (AM1.5, 100 mW/cm²). The open circuit voltage of the cell was measured as 0.82 V, the short circuit current density was measured as 23.46 mA/cm², the filling factor (FF) was measured as 49.62%, and the power conversion efficiency (PCE) was measured as 9.52%. The surface adhesion of the active layer in this example was 36.49 nN. The power conversion efficiency (PCE) of the cell after 5000 times of outward bending cycles was maintained as 94% of an initial value.

Relative to comparative example 1, the surface adhesion is improved by 389%, and the efficiency maintenance after bending cycle is improved by 11%.

### Example 16

An inverted organic solar cell structure based on a thermoplastic elastomer as an elastomer interface layer in this example from bottom to top comprised a conductive substrate, an electron transport layer, an elastomer interface layer (i.e., thermoplastic elastomer layer), an active layer, a hole transport layer and a metal electrode, respectively. The conductive substrate was a polyethylene terephthalate film covered with silver nanowires on the surface; the electron transport layer was a zinc oxide nanoparticle film with a thickness of 10 nm; a solvent used when the thermoplastic elastomer layer was prepared is n-butane, the selected thermoplastic elastomer was SEBS, and the thickness of the elastomer interface layer was 4 nm; in the active layer, a donor material was PM6, an acceptor material wasY6, a mass ratio of the donor material to the acceptor material was 1:1.2, and the concentration of a solution was 8 mg/ml based on PM6; the hole transport layer was vacuum evaporated molybdenum oxide with a thickness of 10 nm; the metal electrode was vacuum evaporated aluminum with a thickness of 150 nm. The performances of the organic solar cell were tested under standard test conditions (AM1.5, 100 mW/cm²). The open circuit voltage of the cell was measured as 0.82 V, the short circuit current density was measured as 24.38 mA/cm², the filling factor (FF) was measured as 69.15%, and the power conversion efficiency (PCE) was measured as 13.82%. The surface adhesion of the active layer in this example was 15.89 nN. The power conversion efficiency (PCE) of the cell after 5000 times of outward bending cycles was maintained as 91% of an initial value.

Relative to comparative example 1, the surface adhesion is improved by 169%, and the efficiency maintenance after bending cycle is improved by 8%.

### Example 17

An inverted organic solar cell structure based on a thermoplastic elastomer as an elastomer interface layer in this example from bottom to top comprised a conductive substrate, an electron transport layer, an elastomer interface layer (i.e., thermoplastic elastomer layer), an active layer, a hole transport layer and a metal electrode, respectively. The conductive substrate was a polyethylene terephthalate film covered with silver nanowires on the surface; the electron transport layer was a zinc oxide nanoparticle film with a thickness of 10 nm; a solvent used when the thermoplastic elastomer layer was prepared is n-butane, the selected thermoplastic elastomer was TPU, and the thickness of the elastomer interface layer was 4 nm; in the active layer, a donor material was PM6, an acceptor material was Y6, a mass ratio of the donor material to the acceptor material was 1:1.2, and the concentration of a solution was 8 mg/ml based on PM6; the hole transport layer was vacuum evaporated molybdenum oxide with a thickness of 10 nm; the metal electrode was vacuum evaporated aluminum with a thickness of 150 nm. The performances of the organic solar cell were tested under standard test conditions (AM1.5, 100 mW/cm²). The open circuit voltage of the cell was measured as 0.81 V, the short circuit current density was measured as 24.96 mA/cm², the filling factor (FF) was measured as 69.52%, and the power conversion efficiency (PCE) was measured as 14.05%. The surface adhesion of the active layer in this example was 18.26 nN. The power conversion efficiency (PCE) of the cell after 5000 times of outward bending cycles was maintained as 90% of an initial value.

Relative to comparative example 1, the surface adhesion is improved by 195%, and the efficiency maintenance after bending cycle is improved by 7%.

### Example 18

An inverted organic solar cell structure based on a thermoplastic elastomer as an elastomer interface layer in this example from bottom to top comprised a conductive substrate, an electron transport layer, an elastomer interface layer (i.e., thermoplastic elastomer layer), an active layer, a hole transport layer and a metal electrode, respectively. The conductive substrate was a polyethylene terephthalate film covered with silver nanowires on the surface; the electron transport layer was a zinc oxide nanoparticle film with a thickness of 10 nm; a solvent used when the thermoplastic elastomer layer was prepared is n-butane, the selected thermoplastic elastomer was TPF, and the thickness of the elastomer interface layer was 4 nm; in the active layer, a donor material was PM6, an acceptor material is Y6, a mass ratio of the donor material to the acceptor material was 1:1.2, and the concentration of a solution was 8 mg/ml based on PM6; the hole transport layer was vacuum evaporated molybdenum oxide with a thickness of 10 nm; the metal electrode was vacuum evaporated aluminum with a thickness of 150 nm. The performances of the organic solar cell were tested under standard test conditions (AM1.5, 100 mW/cm²). The open circuit voltage of the cell was measured as 0.82 V, the short circuit current density was measured as 24.77 mA/cm², the filling factor (FF) was measured as 69.10%, and the power conversion efficiency (PCE) was measured as 14.02%. The surface adhesion of the active layer in this example was 17.65 nN. The power conversion efficiency (PCE) of the cell after 5000 times of outward bending cycles was maintained as 91% of an initial value.

Relative to comparative example 1, the surface adhesion is improved by 188%, and the efficiency maintenance after bending cycle is improved by 8%.

### Example 19

An inverted organic solar cell structure based on a thermoplastic elastomer as an elastomer interface layer in this example from bottom to top comprised a conductive substrate, an electron transport layer, an elastomer interface layer (i.e., thermoplastic elastomer layer), an active layer, a hole transport layer and a metal electrode, respectively. The conductive substrate was a polyethylene terephthalate film covered with silver nanowires on the surface; the electron transport layer was a zinc oxide nanoparticle film with a thickness of 10 nm; a solvent used when the thermoplastic elastomer layer was prepared is n-butane, the selected thermoplastic elastomer was TPAE, and the thickness of the elastomer interface layer was 4 nm; in the active layer, a donor material was PM6, an acceptor material was Y6, a mass ratio of the donor material to the acceptor material was 1:1.2, and the concentration of a solution was 8 mg/ml based on PM6; the hole transport layer was vacuum evaporated molybdenum oxide with a thickness of 10 nm; the metal electrode was vacuum evaporated aluminum with a thickness of 150 nm. The performances of the organic solar cell were tested under standard test conditions (AM1.5, 100 mW/cm²). The open circuit voltage of the cell was measured as 0.82 V, the short circuit current density was measured as 25.01 mA/cm², the filling factor (FF) was measured as 68.82%, and the power conversion efficiency (PCE) was measured as 14.11%. The surface adhesion of the active layer in this example was 15.67 nN. The power conversion efficiency (PCE) of the cell after 5000 times of outward bending cycles was maintained as 89% of an initial value.

Relative to comparative example 1, the surface adhesion is improved by 167%, and the efficiency maintenance after bending cycle is improved by 6%.

### Example 20

An inverted organic solar cell structure based on a thermoplastic elastomer as an elastomer interface layer in this example from bottom to top comprised a conductive substrate, an electron transport layer, an elastomer interface layer (i.e., thermoplastic elastomer layer), an active layer, the elastomer interface layer, a hole transport layer and a metal electrode, respectively. The conductive substrate was a polyethylene terephthalate film covered with silver nanowires on the surface; the electron transport layer was a zinc oxide nanoparticle film with a thickness of 10 nm; a solvent used when the thermoplastic elastomer layer was prepared was n-butane, the selected thermoplastic elastomer was TPAE, and the thickness of the elastomer interface layer was 4 nm; in the active layer, a donor material is PM6, an acceptor material was Y6, a mass ratio of the donor material to the acceptor material was 1:1.2, and the concentration of a solution was 8 mg/ml based on PM6; the hole transport layer was vacuum evaporated molybdenum oxide with a thickness of 10 nm; the metal electrode was vacuum evaporated aluminum with a thickness of 150 nm. The performances of the organic solar cell were tested under standard test conditions (AM1.5, 100 mW/cm²). The open circuit voltage of the cell was measured as 0.81V, the short circuit current density was measured as 24.32 mA/cm², the filling factor (FF) was measured as 68.52%, and the power conversion efficiency (PCE) was measured as 13.44%. The surface adhesion of the active layer in this example was 19.52 nN. The power conversion efficiency (PCE) of the cell after 5000 times of outward bending cycles was maintained as 85% of an initial value.

Relative to comparative example 1, the surface adhesion is improved by 208%, and the efficiency maintenance after bending cycle is improved by 2%.

### Example 21

An inverted organic solar cell structure based on a thermoplastic elastomer as an elastomer interface layer in this example from bottom to top comprised a conductive substrate, an electron transport layer, a lower elastomer interface layer (i.e., thermoplastic elastomer layer), an active layer, an upper elastomer interface layer, a hole transport layer and a metal electrode, respectively. The conductive substrate was a polyethylene terephthalate film covered with silver nanowires on the surface; the electron transport layer was a zinc oxide nanoparticle film with a thickness of 10 nm; a solvent used when the thermoplastic elastomer layer was prepared was n-butane, the selected upper and lower thermoplastic elastomers were SEBS and TPI, with a thickness of 10 nm; in the active layer, a donor material was PM6, an acceptor material was Y6, a mass ratio of the donor material to the acceptor material was 1:1.2, and the concentration of a solution was 8 mg/ml based on PM6; the hole transport layer was vacuum evaporated molybdenum oxide with a thickness of 10 nm; the metal electrode was vacuum evaporated aluminum with a thickness of 150 nm. The performances of the organic solar cell were tested under standard test conditions (AM1.5, 100 mW/cm²). The open circuit voltage of the cell was measured as 0.82 V, the short circuit current density was measured as 24.73 mA/cm², the filling factor (FF) was measured as 67.59%, and the power conversion efficiency (PCE) was measured as 13.70%. The surface adhesion of the active layer in this example was 17.68 nN. The power conversion efficiency (PCE) of the cell after 5000 times of outward bending cycles was maintained as 91% of an initial value.

Relative to comparative example 1, the surface adhesion is improved by 188%, and the efficiency maintenance after bending cycle is improved by 8%.

### Example 22

An inverted organic solar cell structure based on a thermoplastic elastomer as an elastomer interface layer in this example from bottom to top comprised a conductive substrate, an electron transport layer, a lower elastomer interface layer (i.e., thermoplastic elastomer layer), an active layer, an upper elastomer interface layer, a hole transport layer and a metal electrode, respectively. The conductive substrate was a polyethylene terephthalate film covered with silver nanowires on the surface; the electron transport layer was a zinc oxide nanoparticle film with a thickness of 10 nm; a solvent used when the thermoplastic elastomer layer was prepared was n-butane, the selected upper and lower thermoplastic elastomers were TPU and TPI with the thicknesses of 5 nm and 10 nm, respectively; in the active layer, a donor material was PM6, an acceptor material was Y6, a mass ratio of the donor material to the acceptor material was 1:1.2, and the concentration of a solution was 8 mg/ml based on PM6; the hole transport layer was vacuum evaporated molybdenum oxide with a thickness of 10 nm; the metal electrode was vacuum evaporated aluminum with a thickness of 150 nm. The performances of the organic solar cell were tested under standard test conditions (AM1.5, 100 mW/cm²). The open circuit voltage of the cell was measured as 0.81 V, the short circuit current density was measured as 23.88 mA/cm², the filling factor (FF) was measured as 69.15%, and the power conversion efficiency (PCE) was measured as 13.82%. The surface adhesion of the active layer in this example was 21.96 nN. The power conversion efficiency (PCE) of the cell after 5000 times of outward bending cycles was maintained as 92% of an initial value.

Relative to comparative example 1, the surface adhesion is improved by 234%, and the efficiency maintenance after bending cycle is improved by 9%.

### Example 23

An inverted organic solar cell structure based on a thermoplastic elastomer as an elastomer interface layer in this example from bottom to top comprised a conductive substrate, an electron transport layer, a lower elastomer interface layer (i.e., thermoplastic elastomer layer), an active layer, an upper elastomer interface layer, a hole transport layer and a metal electrode, respectively. The conductive substrate was a polyethylene terephthalate film covered with silver nanowires on the surface; the electron transport layer was a zinc oxide nanoparticle film with a thickness of 10 nm; a solvent used when the thermoplastic elastomer layer was prepared was n-butane, the selected upper and lower thermoplastic elastomers were SEBS with thicknesses of 10 nm and 20 nm; in the active layer, a donor material was PM6, an acceptor material was Y6, a mass ratio of the donor material to the acceptor material was 1:1.2, and the concentration of a solution was 8 mg/ml based on PM6; the hole transport layer was vacuum evaporated molybdenum oxide with a thickness of 10 nm; the metal electrode was vacuum evaporated aluminum with a thickness of 150 nm. The performances of the organic solar cell were tested under standard test conditions (AM1.5, 100 mW/cm²). The open circuit voltage of the cell was measured as 0.82 V, the short circuit current density was measured as 24.89 mA/cm², the filling factor (FF) was measured as 69.40%, and the power conversion efficiency (PCE) was measured as 14.16%. The surface adhesion of the active layer in this example was 33.95 nN. The power conversion efficiency (PCE) of the cell after 5000 times of outward bending cycles was maintained as 95% of an initial value.

Relative to comparative example 1, the surface adhesion is improved by 362%, and the efficiency maintenance after bending cycle is improved by 10%.

### Example 24

An inverted organic solar cell structure based on a thermoplastic elastomer as an elastomer interface layer in this example from bottom to top comprised a conductive substrate, a lower elastomer interface layer (i.e., thermoplastic elastomer layer), an electron transport layer, an active layer, a lower elastomer interface layer, a hole transport layer and a metal electrode, respectively. The conductive substrate was a polyethylene terephthalate film covered with silver nanowires on the surface; the electron transport layer was a zinc oxide nanoparticle film with a thickness of 10 nm; a solvent used when the thermoplastic elastomer layer was prepared was n-butane, the selected upper and lower thermoplastic elastomers were SEBS with thicknesses of 10 nm and 20 nm; in the active layer, a donor material was PM6, an acceptor material was Y6, a mass ratio of the donor material to the acceptor material was 1:1.2, and the concentration of a solution was 8 mg/ml based on PM6; the hole transport layer was vacuum evaporated molybdenum oxide with a thickness of 10 nm; the metal electrode was vacuum evaporated aluminum with a thickness of 150 nm. The performances of the organic solar cell were tested under standard test conditions (AM1.5, 100 mW/cm²). The open circuit voltage of the cell was measured as 0.82 V, the short circuit current density was measured as 25.00 mA/cm², the filling factor (FF) was measured as 70.01%, and the power conversion efficiency (PCE) was measured as 14.37%. The surface adhesion of the active layer in this example was 40.00 nN. The power conversion efficiency (PCE) of the cell after 5000 times of outward bending cycles was maintained as 95% of an initial value.

Relative to comparative example 1, the surface adhesion is improved by 250%, and the efficiency maintenance after bending cycle is improved by 20%.

### Example 25

An inverted organic solar cell structure based on a thermoplastic elastomer as an elastomer interface layer in this example from bottom to top comprised a conductive substrate, a lower elastomer interface layer (i.e., thermoplastic elastomer layer), an electron transport layer, an active layer, a hole transport layer, an upper elastomer interface layer and a metal electrode, respectively. The conductive substrate was a polyethylene terephthalate film covered with silver nanowires on the surface; the electron transport layer was a zinc oxide nanoparticle film with a thickness of 10 nm; a solvent used when the thermoplastic elastomer layer was prepared was n-butane, the selected upper and lower thermoplastic elastomers were both SEBS with thicknesses of 15 nm and 30 nm; in the active layer, a donor material was PM6, an acceptor material was Y6, a mass ratio of the donor material to the acceptor material was 1:1.2, and the concentration of a solution was 8 mg/ml based on PM6; the hole transport layer was vacuum evaporated molybdenum oxide with a thickness of 10 nm; the metal electrode was vacuum evaporated aluminum with a thickness of 150 nm. The performances of the organic solar cell were tested under standard test conditions (AM1.5, 100 mW/cm²). The open circuit voltage of the cell was measured as 0.822 V, the short circuit current density was measured as 25.22 mA/cm², the filling factor (FF) was measured as 70.11%, and the power conversion efficiency (PCE) was measured as 14.53%. The surface adhesion of the active layer in this example was 41.20 nN. The power conversion efficiency (PCE) of the cell after 5000 times of outward bending cycles was maintained as 97% of an initial value.

Relative to comparative example 1, the surface adhesion is improved by 310%, and the efficiency maintenance after bending cycle is improved by 25%.

In addition, the inventor of this case conducted a test by using other raw materials, process operations and process conditions described in this specification with reference to the previous examples, and obtained ideal results.

Various aspects, embodiments, features and examples of the present application should be considered as being illustrative in all aspects and are not intended to limit the present application, and the scope of the present application are defined by claims. Those skilled in the art will understand other embodiments, modifications and uses without departing from the spirit and scope of the present application.

Although the present application has been described with reference to illustrative embodiments, various other changes, omissions and/or additions can also be made without departing from the spirit and scope of the present application and elements in examples can be replaced with essential equivalents. In addition, many modifications are made without departing from the scope of the present application so that specific situations or materials are adaptive to the teaching of the present application. Therefore, this article is not intended to limit the present application for use in implementing specific embodiments disclosed in the present application, but rather to include all embodiments within the scope of the attached claims.

What is claimed is:

1. An organic solar cell, comprising a conductive substrate, a hole transport layer, an active layer, an electron transport layer, and a metal electrode, wherein an elastomer interface layer formed by thermoplastic elastomers is arranged between at least two adjacent functional layers, or, upper and lower interfaces of at least one functional layer have an enrichment layer formed by an enrichment of the thermoplastic elastomers.

2. The organic solar cell according to claim 1, wherein the thermoplastic elastomers comprise at least one of a styrenic thermoplastic elastomer, an olefin thermoplastic elastomer, a diene thermoplastic elastomer, a vinyl chloride thermoplastic elastomer, a polyurethane thermoplastic elastomer, an ester thermoplastic elastomer, an amide thermoplastic elastomer, an organic fluorine thermoplastic elastomer, an organic silicon thermoplastic elastomer, and an ethylene thermoplastic elastomer;
and/or, a thickness of the active layer is 20-1000 nm;
and/or, a thickness of the enrichment layer is 0.5-20 nm;
and/or, a thickness of the elastomer interface layer is 0.1-50 nm.

3. The organic solar cell according to claim 1, wherein the elastomer interface layer is arranged between the active layer and the hole transport layer and/or the electron transport layer, the elastomer interface layer is formed by the thermoplastic elastomers, or, upper and lower interfaces of the active layer have the enrichment layer formed by the enrichment of the thermoplastic elastomers;
when the organic solar cell is in an orthostatic structure, the organic solar cell comprises the conductive substrate, the hole transport layer, a first elastomer interface layer formed by the thermoplastic elastomers, the active layer, a second elastomer interface layer formed by the thermoplastic elastomers, the electron transport layer, and the metal electrode, wherein the conductive substrate, the hole transport layer, the first elastomer interface layer formed by the thermoplastic elastomers, the active layer, the second elastomer interface layer formed by the thermoplastic elastomers, the electron transport layer, and the metal electrode are successively laminated; and
when the organic solar cell is in an inverted structure, the organic solar cell comprises the conductive substrate, the electron transport layer, the first elastomer interface layer formed by the thermoplastic elastomers, the active layer, the second elastomer interface layer formed by the thermoplastic elastomers, the hole transport layer, and the metal electrode, wherein the conductive substrate, the electron transport layer, the first elastomer interface layer formed by the thermoplastic elastomers, the active layer, the second elastomer interface layer formed by the thermoplastic elastomers, the hole transport layer, and the metal electrode are successively laminated.

4. The organic solar cell according to claim 1, wherein the elastomer interface layer is arranged between the electron transport layer and the metal electrode, or between the hole transport layer and the metal electrode;
when the organic solar cell is in an orthostatic structure, the organic solar cell comprises the conductive substrate, the hole transport layer, the active layer, the electron transport layer, the elastomer interface layer formed by the thermoplastic elastomers, and the metal electrode, wherein the conductive substrate, the hole transport layer, the active layer, the electron transport layer, the elastomer interface layer formed by the thermoplastic elastomers, and the metal electrode are successively laminated; and
when the organic solar cell is in an inverted structure, the organic solar cell comprises the conductive substrate, the electron transport layer, the active layer, the hole transport layer, the elastomer interface layer formed by the thermoplastic elastomers, and the metal electrode, wherein the conductive substrate, the electron transport layer, the active layer, the hole transport layer, the elastomer interface layer formed by the thermoplastic elastomers, and the metal electrode are successively laminated.

5. The organic solar cell according to claim 1, wherein the conductive substrate comprises a polyethylene terephthalate flexible film, a polyethylene naphthalate flexible film, or a polyimide flexible film covered with one of a metal nanowire, a metal oxide, a metal grid, graphene, and a carbon nanotube on a surface;
and/or, a material of the electron transport layer comprises at least one of a zinc oxide nanoparticle, a sol-gel zinc oxide, PFN-Br, and PDINO, a thickness of the electron transport layer is 10-30 nm;
and/or, a material of the hole transport layer comprises molybdenum oxide and/or PEDOT:PSS, a thickness of the hole transport layer is 10-30 nm;
and/or, a material of the metal electrode comprises aluminum, silver, or gold, a thickness of the metal electrode is 50-1000 nm.

6. A preparation method of the organic solar cell according to claim 1, comprising:
arranging the elastomer interface layer formed by the thermoplastic elastomers between the at least two adjacent functional layers, or, enriching the thermoplastic elastomers at the upper and lower interfaces of the at least one functional layer to form the enrichment layer.

7. The preparation method according to claim 6, comprising:
allowing a mixed system containing a donor material, an acceptor material, and the thermoplastic elastomers to form the active layer, wherein the thermoplastic elastomers are spontaneously enriched at upper and lower interfaces of the active layer to form the enrichment layer;
or, allowing the thermoplastic elastomers to be formed between the active layer and the hole transport layer and/or the electron transport layer to form the elastomer interface layer; and
arranging the elastomer interface layer between the active layer and the hole transport layer and/or the electronic transport layer, or, the upper and lower interfaces of the active layer having the enrichment layer formed by the enrichment of the thermoplastic elastomers.

8. The preparation method according to claim 6, comprising: allowing the thermoplastic elastomers to be formed between the electron transport layer and the metal electrode, or between the hole transport layer and the metal electrode, and arranging the elastomer interface layer between the electron transport layer and the metal electrode, or between the hole transport layer and the metal electrode.

9. The preparation method according to claim 7, comprising:
providing the conductive substrate;
forming the hole transport layer on the conductive substrate;
forming the active layer on the hole transport layer;
forming the elastomer interface layer between the hole transport layer and the active layer;
forming the electron transport layer on the elastomer interface layer; and
forming the metal electrode on the electron transport layer;
or, the preparation method comprises:
providing the conductive substrate;
forming the electron transport layer on the conductive substrate;
forming the active layer on the electron transport layer;
allowing the thermoplastic elastomers to form the elastomer interface layer between the electron transport layer and the active layer;
forming the hole transport layer on the elastomer interface layer; and
forming the metal electrode on the hole transport layer;
or, a method for preparing the active layer in the preparation method comprises:
allowing the mixed system containing the donor material, the acceptor material, and the thermoplastic elastomers to form the active layer, wherein in a process of forming the active layer, the thermoplastic elastomers in the active layer are spontaneously enriched at the upper and lower interfaces of the active layer to form the enrichment layer.

10. The preparation method according to claim 8, comprising:
providing the conductive substrate;
forming the hole transport layer on the conductive substrate;
forming the active layer on the hole transport layer;
forming the electron transport layer on the active layer;
allowing the thermoplastic elastomers to form the elastomer interface layer on the electron transport layer; and
forming the metal electrode on the elastomer interface layer;
or, the preparation method comprises:
providing the conductive substrate;
forming the electron transport layer on the conductive substrate;
forming the active layer on the electron transport layer;
forming the hole transport layer on the active layer;
allowing the thermoplastic elastomers to form the elastomer interface layer on the hole transport layer; and
forming the metal electrode on the elastomer interface layer.

11. The preparation method according to claim 9, comprising: preparing the hole transport layer by using one of vacuum evaporation, spin coating, scraping coating, slit coating, gravure printing, and inkjet printing;
and/or, the preparation method comprises: preparing the metal electrode by using one of the vacuum evaporation, the spin coating, the scraping coating, the slit coating, and the inkjet printing.

12. A method for improving an interfacial adhesion of an organic solar cell, wherein the organic solar cell comprises a conductive substrate, a hole transport layer, an active layer, an electron transport layer, and a metal electrode, the method comprises: arranging an elastomer interface layer formed by thermoplastic elastomers between at least two adjacent functional layers, or, enriching the thermoplastic elastomers at upper and lower interfaces of at least one functional layer to form an enrichment layer.

13. The method for improving the interfacial adhesion of the organic solar cell according to claim 12, wherein the thermoplastic elastomers comprise at least one of a styrenic thermoplastic elastomer, an olefin thermoplastic elastomer, a diene thermoplastic elastomer, a vinyl chloride thermoplastic elastomer, a polyurethane thermoplastic elastomer, an ester thermoplastic elastomer, an amide thermoplastic elastomer, an organic fluorine thermoplastic elastomer, an organic silicon thermoplastic elastomer, and an ethylene thermoplastic elastomer.

14. The method for improving the interfacial adhesion of the organic solar cell according to claim 12, comprising:
allowing a mixed system containing a donor material, an acceptor material, and the thermoplastic elastomers to form the active layer, wherein the thermoplastic elastomers are spontaneously enriched at upper and lower interfaces of the active layer to form the enrichment layer;
or, allowing the thermoplastic elastomers to be formed between the active layer and the hole transport layer and/or the electron transport layer to form the elastomer interface layer; and
arranging the elastomer interface layer between the active layer and the hole transport layer and/or the electronic transport layer, or, the upper and lower interfaces of the active layer having the enrichment layer formed by an enrichment of the thermoplastic elastomers;
or, forming the thermoplastic elastomer between the metal electrode and the hole transport layer and/or the electron transport layer to form the elastomer interface layer; wherein
the method further comprises:
mixing the donor material with the acceptor material to form an active layer ink;
dissolving the thermoplastic elastomers into a first solvent to obtain a mixture, and then blending the mixture with the active layer ink to form the active layer;
a mass ratio of the thermoplastic elastomers to the donor material is less than 2:1; and/or, a thickness of the active layer is 20-1000 nm;
the first solvent comprises at least one of chloroform, chlorobenzene, tetrahydrofuran, dichlorobenzene, toluene, xylene, and trimethylbenzene;
and/or, a thickness of the enrichment layer is 0.5-20 nm.

15. The method according to claim 12, comprising: dissolving the thermoplastic elastomers into a selected solvent to obtain a thermoplastic elastomer solution, and then deposing the thermoplastic elastomer solution on a surface of the active layer, the electron transport layer, or the hole transport layer to form the elastomer interface layer; wherein
a thickness of the elastomer interface layer is 0.1-50 nm;
a preparation method of the elastomer interface layer comprises one of spin coating, scratch coating, slit coating, gravure printing, and inkjet printing;
when the thermoplastic elastomer solution is deposited above the active layer, the selected solvent is a second solvent comprising at least one of an alcohol solvent, cycloalkane, and alkane; and
when the thermoplastic elastomer solution is deposited under the active layer, the selected solvent is a third solvent comprising at least one of the alcohol solvent, the cycloalkane, the alkane, chloroform, chlorobenzene, tetrahydrofuran, dichlorobenzene, toluene, xylene, and trimethylbenzene.

16. The preparation method according to claim 6, wherein in the organic solar cell, the thermoplastic elastomers comprise at least one of a styrenic thermoplastic elastomer, an olefin thermoplastic elastomer, a diene thermoplastic elastomer, a vinyl chloride thermoplastic elastomer, a polyurethane thermoplastic elastomer, an ester thermoplastic elastomer, an amide thermoplastic elastomer, an organic fluorine thermoplastic elastomer, an organic silicon thermoplastic elastomer, and an ethylene thermoplastic elastomer;
and/or, a thickness of the active layer is 20-1000 nm;
and/or, a thickness of the enrichment layer is 0.5-20 nm;
and/or, a thickness of the elastomer interface layer is 0.1-50 nm.

17. The preparation method according to claim 6, wherein in the organic solar cell, the elastomer interface layer is arranged between the active layer and the hole transport layer and/or the electron transport layer, the elastomer interface layer is formed by the thermoplastic elastomers, or, upper and lower interfaces of the active layer have the enrichment layer formed by the enrichment of the thermoplastic elastomers;
when the organic solar cell is in an orthostatic structure, the organic solar cell comprises the conductive substrate, the hole transport layer, a first elastomer interface layer formed by the thermoplastic elastomers, the active layer, a second elastomer interface layer formed by the thermoplastic elastomers, the electron transport layer, and the metal electrode, wherein the conductive substrate, the hole transport layer, the first elastomer interface layer formed by the thermoplastic elastomers, the active layer, the second elastomer interface layer formed by the thermoplastic elastomers, the electron transport layer, and the metal electrode are successively laminated; and
when the organic solar cell is in an inverted structure, the organic solar cell comprises the conductive substrate, the electron transport layer, the first elastomer interface layer formed by the thermoplastic elastomers, the active layer, the second elastomer interface layer formed by the thermoplastic elastomers, the hole transport layer, and the metal electrode, wherein the conductive substrate, the electron transport layer, the first elastomer interface layer formed by the thermoplastic elastomers, the active layer, the second elastomer interface layer formed by the thermoplastic elastomers, the hole transport layer, and the metal electrode are successively laminated.

18. The preparation method according to claim 6, wherein in the organic solar cell, the elastomer interface layer is arranged between the electron transport layer and the metal electrode, or between the hole transport layer and the metal electrode;
when the organic solar cell is in an orthostatic structure, the organic solar cell comprises the conductive substrate, the hole transport layer, the active layer, the electron transport layer, the elastomer interface layer formed by the thermoplastic elastomers, and the metal electrode, wherein the conductive substrate, the hole transport layer, the active layer, the electron transport layer, the elastomer interface layer formed by the thermoplastic elastomers, and the metal electrode are successively laminated; and
when the organic solar cell is in an inverted structure, the organic solar cell comprises the conductive substrate, the electron transport layer, the active layer, the hole transport layer, the elastomer interface layer formed by the thermoplastic elastomers, and the metal electrode, wherein the conductive substrate, the electron transport layer, the active layer, the hole transport layer, the elastomer interface layer formed by the thermoplastic elastomers, and the metal electrode are successively laminated.

19. The preparation method according to claim 6, wherein in the organic solar cell, the conductive substrate comprises a polyethylene terephthalate flexible film, a polyethylene naphthalate flexible film, or a polyimide flexible film covered with one of a metal nanowire, a metal oxide, a metal grid, graphene, and a carbon nanotube on a surface;
and/or, a material of the electron transport layer comprises at least one of a zinc oxide nanoparticle, a sol-gel zinc oxide, PFN-Br, and PDINO, a thickness of the electron transport layer is 10-30 nm;
and/or, a material of the hole transport layer comprises molybdenum oxide and/or PEDOT:PSS, a thickness of the hole transport layer is 10-30 nm;
and/or, a material of the metal electrode comprises aluminum, silver, or gold, a thickness of the metal electrode is 50-1000 nm.

20. The preparation method according to claim 10, comprising: preparing the hole transport layer by using one of vacuum evaporation, spin coating, scraping coating, slit coating, gravure printing, and inkjet printing;
and/or, the preparation method comprises: preparing the metal electrode by using one of the vacuum evaporation, the spin coating, the scraping coating, the slit coating, and the inkjet printing.
